(19) United States
(12) Patent Application Publication
(10) Pub. No.: US 2018/0095151 A1
(43) Pub. Date: Apr. 5, 2018

(54) MAGNETIC RESONANCE IMAGING APPARATUS AND MAGNETIC RESONANCE IMAGING METHOD

(71) Applicant: TOSHIBA MEDICAL SYSTEMS CORPORATION, Otawara-shi (JP)

(72) Inventors: Yuki TAKAI, Nasushiobara (JP); Yoshimori KASSAI, Nasushiobara (JP)

(21) Appl. No.: 15/722,539

(22) Filed: Oct. 2, 2017

(30) Foreign Application Priority Data
Oct. 3, 2016 (JP) 2016-196006

(51) Int. Cl. G01R 33/483

(52) U.S. Cl. CPC G01R 33/4835; G01R 33/485

(57) ABSTRACT

A magnetic resonance imaging apparatus includes sequence controlling circuitry and processing circuitry. When executing a pulse sequence on a plurality of slices by which an inversion recovery pulse to invert longitudinal magnetization of a tissue between a positive value and a negative value is applied to a predetermined one of the slices, and when a standby time period has elapsed a data acquisition is subsequently performed on the predetermined slice, the sequence controlling circuitry exercises control so that the inversion recovery pulse is applied to another one of the slices during the standby time period and so that a data acquisition is performed multiple times on each of the slices while varying the standby time period. The processing circuitry generates an image by using data acquired by the data acquisitions. The sequence controlling circuitry exercises control so that time intervals between the inversion recovery pulses are constant.

### CROSS-REFERENCE TO RELATED APPLICATIONS

This application is based upon and claims the benefit of priority from Japanese Patent Application No. 2016-196006, filed on Oct. 3, 2016; the entire contents of which are incorporated herein by reference.

### FIELD

Embodiments described herein relate generally to a magnetic resonance imaging apparatus and a magnetic resonance imaging method.

### BACKGROUND

During a magnetic resonance imaging process, to generate a T₁ map, for example, the acquisition is performed multiple times by varying the TI (inversion time) periods.

However, when the acquisition performed multiple times is incorporated into a pulse sequence for a multi-slice acquisition, there is a possibility that image quality may be degraded due to an effect called Magnetization Transfer Contrast (MTC) effect, for example.

### BRIEF DESCRIPTION OF THE DRAWINGS

FIG. 1 is a block diagram illustrating a configuration of a magnetic resonance imaging apparatus according to a first embodiment;

FIG. 2 is a drawing for explaining a technical background of the first embodiment;

FIG. 3 is a drawing for explaining a pulse sequence executed by the magnetic resonance imaging apparatus according to the first embodiment;

FIG. 4 is a drawing for explaining a process performed by the magnetic resonance imaging apparatus according to the first embodiment;

FIG. 5 is a drawing for explaining another process performed by the magnetic resonance imaging apparatus according to the first embodiment;

FIG. 6 is a drawing for explaining yet another process performed by the magnetic resonance imaging apparatus according to the first embodiment;

FIG. 7 is a flowchart for explaining an example of a procedure in a process performed by the magnetic resonance imaging apparatus according to the first embodiment;

FIG. 8 is a drawing illustrating an example of a Graphical User Interface (GUI) related to the magnetic resonance imaging apparatus according to the first embodiment;

FIG. 9 is a flowchart for explaining an example of a Procedure in a process performed by a magnetic resonance imaging apparatus according to a second embodiment;

FIG. 10 is a drawing for explaining a pulse sequence executed by the magnetic resonance imaging apparatus according to the second embodiment;

FIG. 11 is a drawing for explaining a pulse sequence executed by a magnetic resonance imaging apparatus according to a third embodiment;

FIG. 12 is a flowchart for explaining an example of a procedure in a process performed by a magnetic resonance imaging apparatus according to a fourth embodiment; and

FIG. 13 is a drawing for explaining a process performed by the magnetic resonance imaging apparatus according to the fourth embodiment.

### DETAILED DESCRIPTION

A magnetic resonance imaging apparatus according to an embodiment includes sequence controlling circuitry and processing circuitry. When executing a pulse sequence on a plurality of slices by which an inversion recovery pulse to invert longitudinal magnetization of a tissue between a positive value and a negative value is applied to a predetermined one of the plurality of slices, and when a standby time period has elapsed a data acquisition is subsequently performed on the predetermined one of the plurality of slices, the sequence controlling circuitry exercises control so that an inversion recovery pulse is applied to another one of the plurality of slices during the standby time period and so that a data acquisition is performed multiple times on each of the plurality of slices while varying the standby time period. The processing circuitry generates an image by using data acquired by the data acquisitions. The sequence controlling circuitry exercises control so that time intervals between the inversion recovery pulses are constant.

Exemplary embodiments of a Magnetic Resonance Imaging apparatus (hereinafter “MRI apparatus”, as appropriate) and a magnetic resonance imaging method will be explained below with reference to the accompanying drawings. Possible embodiments are not limited to the embodiments described below. Further, in principle, the explanation of each of the embodiments is similarly applicable to any other embodiments.

### First Embodiment

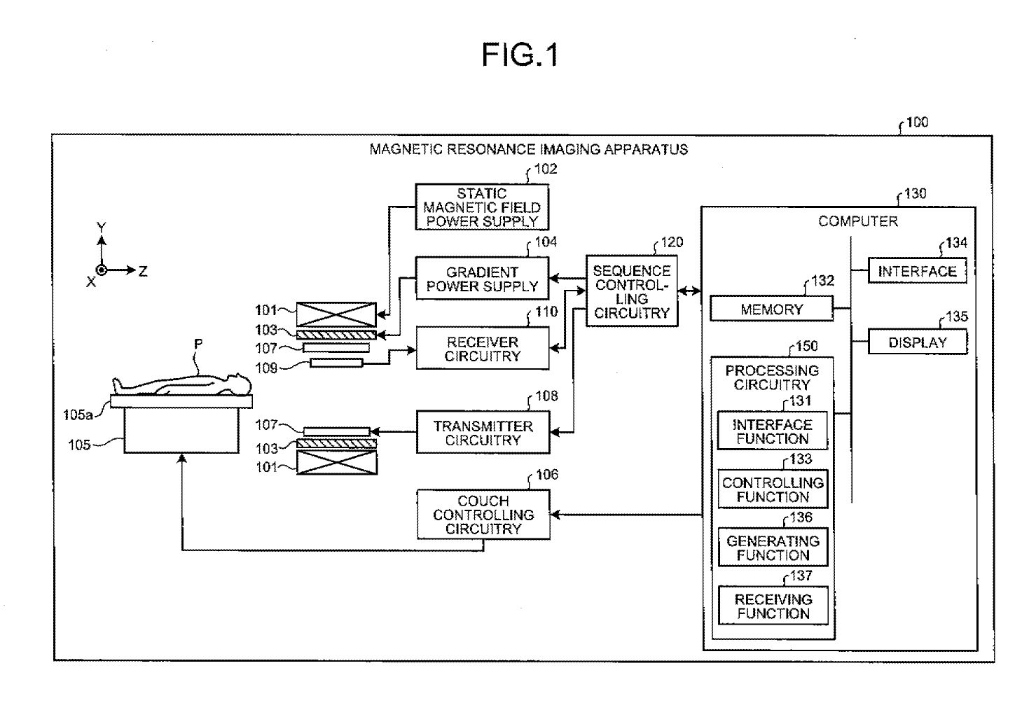

FIG. 1 is a block diagram illustrating a configuration of an MRI apparatus 100 according to a first embodiment. As illustrated in FIG. 1, the MRI apparatus 100 includes a static magnetic field magnet 101, a static magnetic field power supply 102, a gradient coil 103, a gradient power source 104, a couch 105, couch controlling circuitry 106, a transmitter coil 107, transmitter circuitry 100, a receiver coil 109, receiver circuitry 110, sequence controlling circuitry 120, and a computer 130 (which may be referred to as an “image processing apparatus”). The MRI apparatus 100 does not include an examined subject P representing a human body, for example. Further, the configuration illustrated in FIG. 1 is merely an example. For instance, the sequence controlling circuitry 120 and any of the constituent elements of the computer 130 may be integrated together or separated from the rest as appropriate.

The static magnetic field magnet 101 is a magnet formed to have a hollow and substantially circular cylindrical shape and is configured to generate a static magnetic field in the space on the inside thereof. For example, the static magnetic field magnet 101 may be realized with a superconductive magnet or the like and is configured to be magnetized by receiving a supply of an electric current from a static magnetic field power supply 102. The static magnetic field power supply 102 is configured to supply the electric current to the static magnetic field magnet 101. The static magnetic field magnet 101 may be a permanent magnet. In that situation, the MRI apparatus 100 does not necessarily have to include the static magnetic field power supply 102. Further, the static magnetic field power supply 102 may be provided separately from the MRI apparatus 100.

The gradient coil 103 is a coil formed to have a hollow and substantially circular cylindrical shape and is disposed on the inside of the static magnetic field magnet 101. The gradient coil 103 is formed by combining together three coils corresponding to X-, Y-, and Z-axes that are orthogonal to one another. These three coils are configured to individually receive a supply of an electric current from the gradient power source 104 and to generate gradient magnetic fields of which the magnetic field intensities change along the X-, Y-, and Z-axes. The gradient magnetic fields along the X-, Y-, and Z-axes generated by the gradient coil 103 may be, for example, a slicing gradient magnetic field Gs, a phase-encoding gradient magnetic field Ge, and a read-out gradient magnetic field Gr. The gradient power source 104 is configured to supply the electric current to the gradient coil 103.

The couch 105 includes a couchtop 105a on which the subject P is placed. Under control of the couch controlling circuitry 106, the couchtop 105a is inserted into the hollow space (an image taking opening) of the gradient coil 103, while the subject P is placed thereon. Usually, the couch 105 is installed in such a manner that the longitudinal direction thereof extends parallel to the central axis of the static magnetic field magnet 101. Under control of the computer 130, the couch controlling circuitry 106 is configured to drive the couch 105 so as to move the couchtop 105a in the longitudinal direction and the up-and-down direction.

The transmitter coil 107 is disposed on the inside of the gradient coil 103 and is configured to generate a radio frequency magnetic field by receiving a supply of Radio Frequency (RF) pulse from the transmitter circuitry 108. The transmitter circuitry 108 is configured to supply the transmitter coil 107 with the RF pulse corresponding to a Larmor frequency determined by the type of the target atom and the magnetic field intensities.

The receiver coil 109 is disposed on the inside of the gradient coil 103 and is configured to receive magnetic resonance signals (hereinafter, “MR signals”) emitted from the subject P due to an influence of a radio frequency magnetic field. When having received the MR signals, the receiver coil 109 is configured to output the received MR signals to the receiver circuitry 110.

The transmitter coil 107 and the receiver coil 109 described above are merely examples. The coil structure may be configured by selecting one coil or combining two or more coils from among the following: a coil having only a transmitting function; a coil having only a receiving function; and a coil having a transmitting/receiving function.

The receiver circuitry 110 is configured to detect the MR signals output from the receiver coil 109 and to generate magnetic resonance data (hereinafter, “MR data”) on the basis of the detected MR signals. More specifically, the receiver circuitry 110 generates the MR data by applying a digital conversion to the MR signals output from the receiver coil 109. Further, the receiver circuitry 110 is configured to transmit the generated MR data to the sequence controlling circuitry 120. The receiver circuitry 110 may be provided on the gantry device side where the static magnetic field magnet 101, the gradient coil 103, and the like are provided.

The sequence controlling circuitry 120 is configured to perform an image taking process on the subject P, by driving the gradient power source 104, the transmitter circuitry 108, and the receiver circuitry 110, on the basis of sequence information transmitted thereto from the computer 130. In this situation, the sequence information is information defining a procedure to perform the image taking process. The sequence information defines: the intensity of the electric current supplied from the gradient power source 104 to the gradient coil 103 and the timing with which the electric current is to be supplied; the intensity of the RF pulse supplied from the transmitter circuitry 108 to the transmitter coil 107 and the timing with which the RF pulse is to be applied; the timing with which the MR signals are to be detected by the receiver circuitry 110, and the like. For example, the sequence controlling circuitry 120 is configured with an integrated circuit such as an Application Specific Integrated Circuit (ASIC) or a Field Programmable Gate Array (FPGA), or an electronic circuit such as a Central Processing Unit (CPU) or a Micro Processing Unit (MPU).

When having received the MR data from the receiver circuitry 110 as a result of the image taking process performed on the subject P by driving the gradient power source 104, the transmitter circuitry 108, and the receiver circuitry 110, the sequence controlling circuitry 120 transfers the received MR data to the computer 130. The computer 130 is configured to exercise overall control of the MRI apparatus 100 and to generate images and the like. The computer 130 includes storage circuitry 132, an input device 134, a display 135, and processing circuitry 150. The processing circuitry 150 includes an interface function 131, a controlling function 133, a generating function 136, and a receiving function 137.

In the first embodiment, processing functions implemented by the interface function 131, the controlling function 133, the generating function 136, and the receiving function 137 are stored in the storage circuitry 132 in the form of computer-executable programs. The processing circuitry 150 is a processor configured to realize the functions corresponding to the computer programs (hereinafter, “programs”) by reading the programs from the storage circuitry 132 and executing the read programs. In other words, the processing circuitry 150 that has read the programs has the functions illustrated within the processing circuitry 150 in FIG. 1. Although FIG. 1 illustrates the example in which the single processing circuitry 130 realizes the processing functions implemented by the interface function 131, the controlling function 133, the generating function 136, and the receiving function 137, another arrangement is also acceptable in which the processing circuitry 150 is structured by combining together a plurality of independent processors so that the functions are realized as a result of the processors executing the programs.

In other words, each of the abovementioned functions may be structured as a program so that the single processing circuitry executes the programs. Alternatively, specific one or more of the functions may be installed in each of the dedicated and independent program-executing circuits.

The term “processor” used in the above explanation denotes, for example, a Central Processing Unit (CPU), a Graphical Processing Unit (GPU), or a circuit such as an Application Specific Integrated Circuit (ASIC) or a programmable logic device (e.g., a Simple Programmable Logic Device [SPLD], a Complex Programmable Logic Device [CPLD], or a Field Programmable Gate Array [FPGA]). The one or more processors realize the functions thereof by reading and executing the programs stored in the storage circuitry 132.

Instead of storing the programs into the storage circuitry 132, it is also acceptable to directly incorporate the programs into the circuits of the one or more processors. In that situation, the one or more processors realize the functions thereof by reading and executing the programs incorporated in the circuits thereof. Similarly, the couch controlling circuitry 106, the transmitter circuitry 108, the receiver circuitry 110, and the like are also each configured with an electronic circuit such as the processor described above.

The sequence controlling circuitry 120, the generating function 136, and the receiving function 137 are examples of a sequence controlling unit, a generating unit, and a receiving unit, respectively.

By employing the interface function 131, the processing circuitry 150 is configured to transmit the sequence information to the sequence controlling circuitry 120 and to receive the. MR data from the sequence controlling circuitry 120. Further, when having received the MR data, the processing circuitry 150, which includes the interface function 131, stores the received MR data into the storage circuitry 132. The MR data stored in the storage circuitry 132 is arranged into a k-space by the controlling function 133. As a result, the storage circuitry 132 stores therein k-space data.

The storage circuitry 132 stores therein the MR data received by the processing circuitry 150 including the interface function 131, the k-space data arranged in the k-space by the processing circuitry 150 including the controlling function 133, image data generated by the processing circuitry 150 including the generating function 136, and the like. For example, the storage circuitry 132 is configured by using a semiconductor memory element such as a Random Access Memory (RAM) or a flash memory, a hard disk, an optical disk, or the like.

The input device 134 is configured to receive various types of instructions and inputs of information from the operator. For example, the input device 134 is configured with a pointing device such as a mouse or a trackball, a selecting device such as a mode changing switch, and/or an input device such as a keyboard. Under control of the processing circuitry 150 including the controlling function 133, the display 135 is configured to display a Graphical User Interface (GUI) used for receiving inputs of image taking conditions, as well as images and the like generated by the processing circuitry 150 including the generating function 136. The display 135 may be, for example, a display device such as a liquid crystal display monitor.

By employing the controlling function 133, the processing circuitry 150 is configured to exercise overall control of the MRI apparatus 100, so as to control image taking processes, image generating processes, image displaying processes, and the like. For example, the processing circuitry 150 including the controlling function 133 receives an input of an image taking condition (e.g., an image taking parameter) via the GUI and generates the sequence information according to the received image taking condition. Further, the processing circuitry 150 including the controlling function 133 transmits the generated sequence information to the sequence controlling circuitry 120.

By employing the image generating function 136, the processing circuitry 150 reads the k-space data from the storage circuitry 132 and generates an image by performing a reconstructing process such as a Fourier transform on the read k-space data.

By employing the receiving function 137, the processing circuitry 150 receives an input from the user via the input device 134, for example. Details of the receiving function 137 will be explained later.

Next, a background of the MRI apparatus according to an embodiment will be explained briefly.

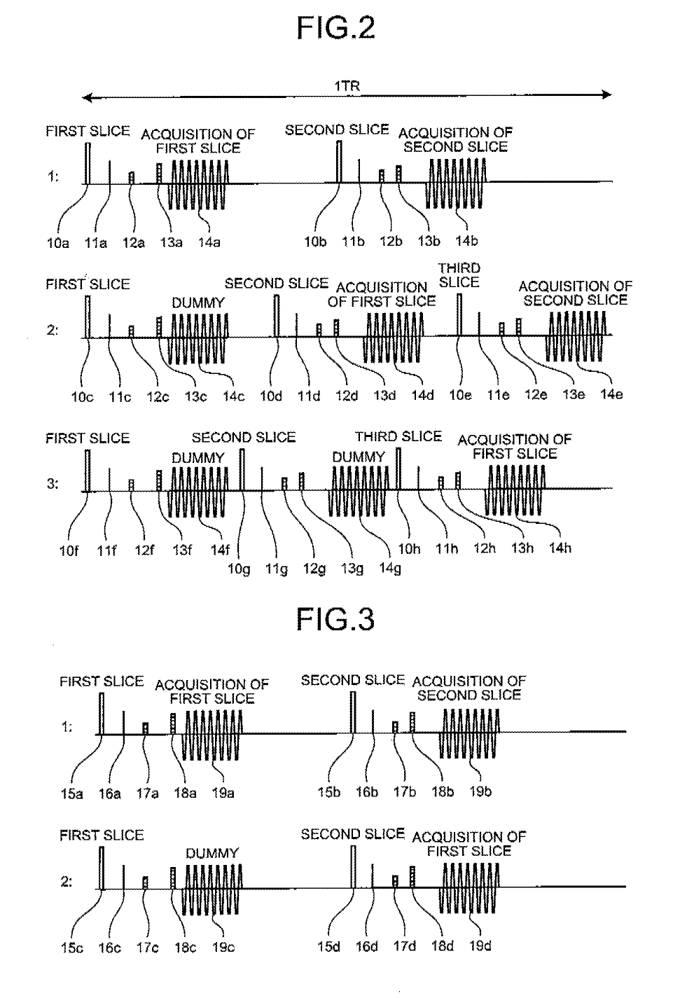

FIG. 2 is a drawing for explaining a technical background of the first embodiment. FIG. 2 illustrates an example of a pulse sequence used for acquiring a plurality of slices. For example, the sequence may be used for performing a two-dimensional spin-echo Echo Planar Imaging (EFI) process. The horizontal axis expresses time. In FIG. 2, at first, the pulses are applied according to the sequence in the top section, then according to the sequence in the middle section, and subsequently according to the sequence in the bottom section. For example, each of the top, middle, and bottom sections corresponds to a sequence in one Repetition Time (“1 TR”), which denotes a time interval between excitation pulses used for exciting mutually the same slices.

Reference characters 10a, 10b, 10c, 10d, 10e, 10f, 10g, and 10h denote Inversion Recovery (IR) pulses that are excitation pulses used for inverting longitudinal magnetization of a tissue. Reference characters 11a, 11b, 11c, 11d, 11e, 11f, 11g, and 11h denote fat saturation pulses used for suppressing signals of fat. Reference characters 12a, 12b, 12c, 12d, 12e, 12f, 12g, and 12h denote 90-degree pulses. Reference characters 13a, 13b, 13c, 13d, 13e, 13f, 13g, and 13h denote 180-degree pulses. By combining each of the 90-degree pulses with a corresponding one of the 180-degree pulses, an echo is generated, for example. While the echo is being generated, an acquisition is performed. Reference characters 14a, 14b, 14c, 14d, 14e, 14f, 14g, and 14h denote data acquisitions. For example, during a two-dimensional spin-echo EPI process, in each of the data acquisitions, the two-dimensional k-space plane of one slice is swept by a gradient magnetic field and a blipped gradient magnetic field that continuously change so as to acquire two-dimensional k-space data of the one slice.

First, in the top section of FIG. 2, the sequence controlling circuitry 120 excites a first slice by applying the IR pulse 10a. After applying the fat saturation pulse 11a, the sequence controlling circuitry 120 applies the 90-degree pulse 12a and the 180-degree pulse 13a with respect to the first slice, so as to generate a spin echo. While the spin echo is being generated, the sequence controlling circuitry 120 performs the data acquisition 14a on slice 1.

After that, the sequence controlling circuitry 120 excites a second slice by applying the IR pulse 10b. After applying the fat saturation pulse 11b, the sequence controlling circuitry 120 applies the 90-degree pulse 12b and the 180-degree pulse 13b with respect to the second slice, so as to generate a spin echo. While the spin echo is being generated, the sequence controlling circuitry 120 performs the data acquisition 14b on slice 2. In this manner, when the sequence controlling circuitry 120 has repeatedly performed the data acquisition on all the slices, the data acquisitions in the one TR are finished.

Subsequently, as illustrated in the middle section of FIG. 2, with respect to slice 1, the sequence controlling circuitry 120 excites the first slice by applying the IR pulse 10c and inverts longitudinal magnetization of the first slice. The fat saturation pulse 11c, the 90-degree pulse 12c, the 180-degree pulse 13c, and the data acquisition 14c are dummies, for example.

After that, with respect to slice 2, the sequence controlling circuitry 120 excites the second slice by applying the IR pulse 10d and inverts the longitudinal magnetization of the second slice.

Subsequently, after applying the fat saturation pulse 11d, the sequence controlling circuitry 120 applies the 90-degree pulse 12d and the 180-degree pulse 13d with respect to the first slice so as to generate a spin echo. while the spin echo is being generated, the sequence controlling circuitry 120 performs the data acquisition 14d on slice 1. In this situation, the TI (inversion time) period with respect to the first slice is the time period from when the IR pulse 10c is applied to the data acquisition 14d.

In this situation, because the IR pulse 10d, the 90-degree pulse 12d, the 180-degree pulse 13d, and 50 on are for the second slice, these pulses have no impact on the first slice.

Subsequently, with respect to a third slice, the sequence controlling circuitry 120 excites the third slice by applying the IR pulse 10e and inverts the longitudinal magnetization of the third slice. After applying the fat saturation pulse 11e, the sequence controlling circuitry 120 applies the 90-degree pulse 12e and the 180-degree pulse 13e with respect to the second slice, so as to generate a spin echo. After that, during the data acquisition 14e, the data acquisition is performed on the second slice.

When the acquisitions corresponding to the one TR have been finished, as illustrated in the bottom section of FIG. 2, with respect to slice 1, the first slice is excited by applying the IR pulse 10c. The fat saturation pulse 11f, the 90-degree pulse 12f, the 180-degree pulse 13f, and the data acquisition 14f are dummies similarly to the example above. After that, with respect to slice 2, the second slice is excited by applying the IR pulse 10g. The fat saturation pulse 11g, the 90-degree pulse 12g, the 180-degree pulse 13g, and the data acquisition 14g are dummies. Subsequently, with respect to the third slice, the third slice is excited by applying the IR pulse 10h. With respect to the fat saturation pulse 11h, the sequence controlling circuitry 120 applies the 90-degree pulse 12h and the 180-degree pulse 13h with respect to the first slice and performs the data acquisition 14h on the first slice.

When performing the data acquisitions on multiple slices, the sequence controlling circuitry 120 may execute, as described above, the pulse sequences in a “nested” manner. With this arrangement, the sequence controlling circuitry 120 is able to perform the data acquisitions while saving acquisition time, with respect to the plurality of TI periods.

However, with the arrangement described above, the application time intervals of the IR pulses are not uniform. For example, the time period from when the IR pulse 10a is applied to when the IR pulse 10b is applied, the time period from when the IR pulse 10c is applied to when the IR pulse 10d is applied, and the time period from when the IR pulse 10f is applied to when the IR pulse 10g is applied are different from one another.

As a first issue, when the application time intervals are different among the IR pulses, the number of times the IR pulse is applied per unit time period varies. Accordingly, the magnitude of the MTC effect varies between when the number of times the IR pulse is applied is small and when the number of times is large per unit time period. This may be a cause of errors in the image. Consequently, it is desirable to arrange the application time intervals of the IR pulses to be uniform.

As a second issue, when the application time intervals of the IR pulses are not uniform, because it is impossible to manage the IR pulses with one protocol (which is the unit in which image taking conditions are set and managed), it becomes necessary to set image taking conditions for each of the IR pulses, which is cumbersome.

in view of the background circumstances described above, the sequence controlling circuitry 120 included in the MRI apparatus 100 according to an embodiment is configured to apply excitation pulses (e.g., the inversion recovery pulses) at such application times that the time intervals between the plurality of excitation pulses are constant, while sequentially changing the slice to be excited thereby. With this arrangement, it is possible to improve image quality. In addition, it is also possible to enhance usability.

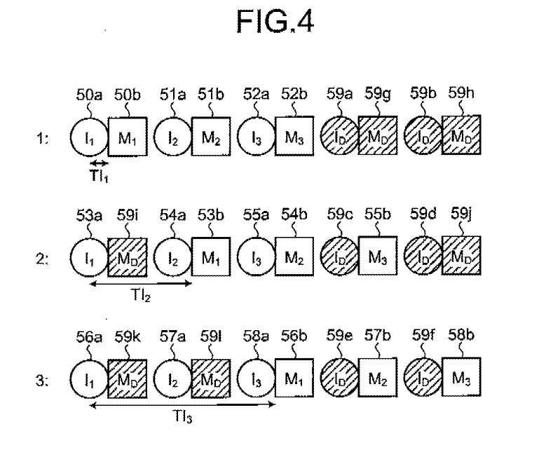

The above configuration will be explained with reference to FIGS. 3 to 8. First, with reference to FIGS. 3 and 4, a schematic configuration of a pulse sequence executed by the sequence controlling circuitry 120 will be explained. FIG. 3 is a drawing for explaining the pulse sequence executed by the MRI apparatus according to the first embodiment. FIG. 4 is a drawing for explaining a process performed by the MRX apparatus according to the first embodiment.

In FIG. 3, the reference characters 15a, 15b, 15c, and 15d denote IR pulses that are excitation pulses to invert the longitudinal magnetization of a tissue (to change the longitudinal magnetization of the tissue either from a positive value to a negative value or from a negative value to a positive value). The reference characters 16a, 16b, 16c, and 16d denote fat saturation pulses used for suppressing signals of fat. The reference characters 17a, 17b, 17c, and 17d denote 90-degree pulses. The reference characters 18a, 18b, 18c, and 18d denote 180-degree pulses. By combining each of the 90-degree pulses with a corresponding one of the 180-degree pulses, an echo is generated. While the echo is being generated, an acquisition is performed. The reference characters 19a, 19b, 19c, and 19d denote data acquisitions.

First, in the top section of FIG. 3, the sequence controlling circuitry 120 excites a first slice by applying an IR pulse 15a. After applying the fat saturation pulse 16a, the sequence controlling circuitry 120 applies the 90-degree pulse 17a and the 180-degree pulse 18a with respect to the first slice, so as to generate a spin echo. While the spin echo is being generated, the sequence controlling circuitry 120 performs the data acquisition 19a on slice 1.

After that, the sequence controlling circuitry 120 excites a second slice by applying the IR pulse 15b. After applying the fat saturation pulse 16b, the sequence controlling circuitry 120 applies the 90-degree pulse 17b and the 180-degree pulse 18b with respect to the second slice, so as to generate a spin echo. While the spin echo is being generated, the sequence controlling circuitry 120 performs the data acquisition 19b on the second slice. In this manner, when the sequence controlling circuitry 120 has repeatedly performed the data acquisition on all the slices, the data acquisitions in the one TR are finished. In this situation, the one TR denotes, for example, the time interval between when the IR pulse 15a used for exciting the first slice is applied and when the IR pulse 15c used for exciting the first slice again is applied. In this manner, the sequence controlling circuitry 120 performs the acquisitions on the plurality of slices by applying the plurality of excitation pulses each of which excites a corresponding one of the plurality of slices, during the one TR, which is the time interval between the excitation pulses used for exciting mutually the same slices. For example, in the example in FIG. 3, during the one TR, the sequence controlling circuitry 120 applies the plurality of IR pulses that excite the first slice and the second slice. On the basis of those IR pulses, the sequence controlling circuitry 120 performs the acquisitions on the first slice and the second slice.

After that, when the data acquisitions in the one TR have been finished, as illustrated in the bottom section of FIG. 3, with respect to the first slice, the sequence controlling circuitry 120 excites the first slice by applying the IR pulse 15c and inverts the longitudinal magnetization of the first slice. The fat saturation pulse 16c, the 90-degree pulse 17c, the 180-degree pulse 18c, and the data acquisitions 19c are dummies, for example.

In this manner, when the data acquisition is not performed on any of the plurality of slices during the time period between when an inversion recovery pulse is applied to the first slice and when an inversion recovery pulse is applied to the second slice different from the first slice, the sequence controlling circuitry 120 either applies a dummy pulse or performs a dummy acquisition.

Subsequently, with respect to the second slice, the sequence controlling circuitry 120 excites the second slice by applying the IR pulse 15d and inverts the longitudinal magnetization of the second slice.

Subsequently, after applying the fat saturation pulse 16d, the sequence controlling circuitry 120 applies the 90-degree pulse 17d and the 180-degree pulse 18d with respect to the first slice, so as to generate a spin echo. While the spin echo is being generated, the sequence controlling circuitry 120 performs the data acquisition 19d on the first slice. In this situation, the TI period with respect to the first slice is the time period from when the IR pulse 15c is applied to the data acquisition 19d.

In this situation, because the IR pulse 15d, the 90-degree pulse 17d, and the 180-degree pulse 18d are for the second slice, these pulses have no impact on the first slice.

In the present example in FIG. 3, the time intervals between the excitation pulses are constant, unlike the example in FIG. 2. In other words, the sequence controlling circuitry 120 applies the plurality of excitation pulses at such application times that the time intervals between the plurality of excitation pulses are constant. More specifically, the sequence controlling circuitry 120 applies the IR pulses at such application times that the time period from when the IR pulse 15a is applied to when the TR pulse 15b is applied and the time period from when the IR pulse 15c is applied and to when the IR pulse 15d is applied are constant. Accordingly, the number of times the IR pulse is applied per unit time period is equal between the top section and the bottom section of FIG. 3. Consequently, the impacts of the MTC effect are equal between the top section and the bottom section of FIG. 3. In this situation, the IR pulse 15b is an IR pulse used for exciting the first slice, while the IR pulse 15d is an IR pulse used for exciting the second slice, and the IR pulse 15c again excites the first slice. Accordingly, in the top section of FIG. 3, the time period from when the IR pulse 15a is applied to the data acquisition 19a is the TI period with respect to the first slice. In the bottom section of FIG. 3, the time period from when the IR pulse 15c is applied to the data acquisition 19d is the TI period with respect to the first slice. As explained herein, the sequence controlling circuitry 120 is able to acquire the data with respect to the plurality of TI periods, while maintaining the condition that the impacts of the MTC effect are equal.

FIG. 4 schematically illustrates such a pulse sequence. The reference characters 50a, 51a, 52a, 53a, 54a, 55a, 56a, 57a, and 58a denote IR pulses. The IR pulses 50a, 53a, and 56a excite the first slice. The IR pulses 51a, 54a, and 57a excite the second slice. The IR pulses 52a, 55a, and 58a excite the third slice. The reference characters 50b, 51b, 52b, 53b, 54b, 55b, 56b, 57b, 58b, and 59g denote data acquisitions. In the data acquisitions 50b, 53b, and 56b, the data related to the first slice is acquired. In the data acquisitions 51b, 54b, and 57b, the data related to the second slice is acquired. In the data acquisition 52b, 55b, and 58b, the data related to the third slice is acquired. The reference characters 59a, 59b, 59c, 59d, 59e, and 59f denote dummy pulses. The reference characters 59g, 59h, 59i, 59j, 59k, and 59l denote dummy acquisitions. With regard to each of the dummy pulses, a pulse may be applied as a dummy or nothing may be applied. With regard to each of the dummy acquisitions, an acquisition may be performed as a dummy or nothing may be acquired.

In the following sections, an example will be explained in which the sequence controlling circuitry 120 performs acquisitions on three slices, namely, the first slice, the second slice, and the third slice.

As illustrated in the top section of FIG. 4, at first, with respect to the first slice, the sequence controlling circuitry 120 applies the IR pulse 50a and acquires data in the data acquisition 50b. Similarly, with respect to the second slice, the sequence controlling circuitry 120 applies the IR pulse 51a and acquires data in the data acquisition 51b. Further, with respect to the third slice, the sequence controlling circuitry 120 applies the TR pulse 52a and acquires data in the data acquisition 52b.

When the application time of the IR pulse 50a is expressed as t0, the time of the data acquisition 50b is expressed as t0+Δ, and the application time interval between the IR pulses is expressed as x, the sequence controlling circuitry 120 applies, in one example, the IR pulse 50a at the time t0, the IR pulse 51a at the time t0+x, and the IR pulse 52a at the time t0+2x.

Further, the sequence controlling circuitry 120 performs, in one example, the data acquisition 50b at the time t0+Δ, the data acquisition 51b at the time t0+Δ+x, and the data acquisition 52b at the time t0+Δ+2x. Accordingly, the TI period is Δ in each of all the procedures.

Subsequently, the sequence controlling circuitry 120 applies the dummy pulse 59a at the time t0+3x and performs the dummy acquisition 59g at the time t0+Δ+3x. After that, the sequence controlling circuitry 120 applies the dummy pulse 59b at the time t0+4x and performs the dummy acquisition 59h at the time t0+Δ+4x.

After that, as illustrated in the middle section of FIG. 4, with respect to the first slice, the sequence controlling circuitry 120 applies the IR pulse 53a and performs the data acquisition 53b. Similarly, with respect to the second slice, the sequence controlling circuitry 120 applies the IR pulse 54a and performs the data acquisition 54b. Further, with respect to the third slice, the sequence controlling circuitry 120 applies the IR pulse 55a and performs the data acquisition 55b. When the application time of the IR pulse 53a is expressed as t1, the application time interval between the IR pulses is expressed as x, and the time at which the data acquisition 53b is performed is expressed as t1+Δ+x, the sequence controlling circuitry 120 applies, in one example, the IR pulse 53a at the time t1, the IR pulse 54a at the time t1+x, and the IR pulse 55a at the time t1+2x. Further, the sequence controlling circuitry 120 performs, in one example, the data acquisition 53b at the time t1+Δ+x, the data acquisition 54b at the time t1+Δ+2x, and the data acquisition 55b at the time t1+Δ+3x. In this situation, the TI period is Δ+x in each of all the procedures.

Further, the sequence controlling circuitry 120 applies the dummy pulses 59c and 59d at the time t1+3x and at the time t1+4x, respectively. The sequence controlling circuitry 120 performs the dummy acquisitions 59i and 59j at the time t1+Δ and at the time t1+Δ+4x, respectively.

Subsequently, as illustrated in the bottom section of FIG. 4, with respect to the first slice, the sequence controlling circuitry 120 applies the IR pulse 56a and acquires data in the data acquisition 56b. Similarly, with respect to the second slice, the sequence controlling circuitry 120 applies the IR pulse 57a and acquires data in the data acquisition 57b. Further, with respect to the third slice, the sequence controlling circuitry 120 applies the IR pulse 58a and acquires data in the data acquisition 58b. When the calculation is performed similarly, the TI period is Δ+2x in each of all the procedures.

Further, the sequence controlling circuitry 120 applies the dummy pulses 59e and 59f and performs the dummy acquisitions 59i and 59j with the timing indicated in FIG. 4.

As explained above, when the sequence controlling circuitry 120 executes the pulse sequence on the plurality of slices by which the inversion recovery pulse to invert the longitudinal magnetization of the tissue between a positive value and a negative value is applied to a predetermined one of the slices, and when the standby period has elapsed the data acquisition is subsequently performed on the predetermined slice, the sequence controlling circuitry 120 exercises control so that the inversion recovery pulse is applied to another one of the plurality of slices during the standby time period. For example, the sequence controlling circuitry 120 exercises control so that, during the standby period between when the IR pulse 53a is applied with respect to the first slice and when the data acquisition 53b is performed on the first slice, the IR pulse 54a is applied to the second slice. Further, the sequence controlling circuitry 120 exercises control so that, during the standby period between when the IR pulse 56a is applied with respect to the first slice and when the data acquisition 56b is performed on the first slice, the IR pulse 57a is applied to the second slice and the IR pulse 58a is applied to the third slice.

By using the data acquired in these data acquisitions, the processing circuitry 150 generates an image such as a T₁ map.

Further, the sequence controlling circuitry 120 performs a plurality of sets of acquisitions (performs the data acquisitions multiple times), while each set of acquisitions corresponds to the acquisitions performed on the plurality of slices during the one TR. For example, the top section, the middle section, and the bottom section in FIG. 4 each correspond to one set of acquisitions. As observed from these sections in the drawing, while the acquisitions performed on the plurality of slices during one TR are considered as a set of acquisitions, the sequence controlling circuitry 120 performs a plurality of sets of acquisitions by applying a plurality of excitation pulses while varying, among the sets, the slice to be excited at each of the application times.

Further, the sequence controlling circuitry 120 acquires the plurality of pieces of data with respect to mutually-different TI periods, by performing the plurality, of sets of acquisitions (by performing the data acquisitions multiple times). More specifically, the sequence controlling circuitry 120 is able to acquire data with respect to a TI period that is congruent to a predetermined parameter A modulo x, where x denotes the application time interval between the IR pulses. For example, when Δ=100 msec and x=500 msec are satisfied, the sequence controlling circuitry 120 is able to perform acquisitions with respect to TI=100 msec, 600 msec, 1,100 msec, 1,600 msec, and 2,100 msec.

The values of TI periods with which the acquisitions can be performed are not limited to the examples above. For instance, because pulse sequences are designed to include certain leeway such as standby time periods, the sequence controlling circuitry 120 is able to acquire data with respect to TI periods having values different from those of the TI periods explained above, by making adjustments to the leeway time.

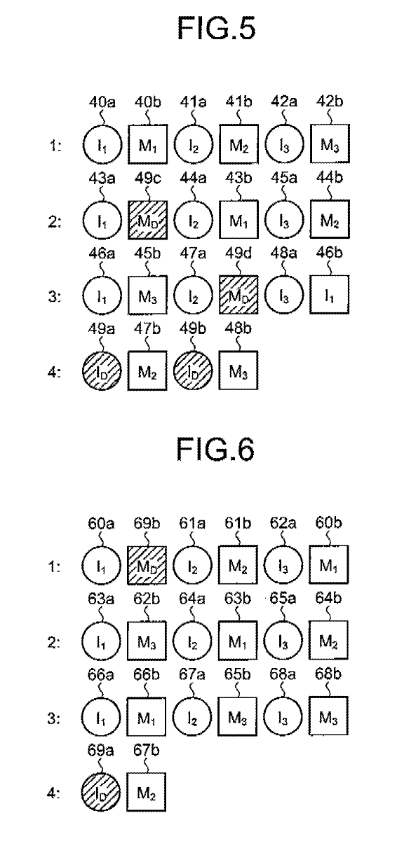

Further, the order in which the acquisitions are performed on the slices and the manner in which the dummy pulses are applied and the dummy acquisitions are performed are not limited to the examples in the embodiment above. Specific examples will be explained with reference to FIGS. 5 to 7. FIGS. 5 to 7 are drawings for explaining processes performed by the MRI apparatus according to the first embodiment.

First, the example in FIG. 5 will be explained. With reference to FIG. 5, an example will be explained in which the image taking time period is shortened by performing an acquisition related to a “previous TI period” instead of dummy pulses and dummy acquisitions.

In FIG. 5, Reference characters 40a, 41a, 42a, 43a, 44a, 45a, 46a, 47a, and 48a denote IR pulses. The IR pulses 40a, 43a, and 46a excite the first slice. IR pulses 41a, 44a, and 47a excite the second slice. IR pulses 42a, 45a, and 48a excite the third slice. Reference characters 40b, 41b, 42b, 43b, 44b, 45b, 46b, 47b, and 48b denote data acquisitions. In data acquisitions 40b, 43b, and 46b, data related to the first slice is acquired. In data acquisitions 41b, 44b, and 47b, data related to the second slice is acquired. In data acquisitions 42b, 45b, and 48b, data related to the third slice is acquired. Reference characters 49a and 49b denote dummy pulses. Reference characters 59c and 59d denote dummy acquisitions.

When FIG. 5 is compared with FIG. 4, while the IR pulse 46a and the data acquisition 45b in FIG. 5 exhibit different patterns from those in FIG. 4, the rest of FIG. 5 is the same as FIG. 4. Accordingly, the duplicate explanation of such a part of FIG. 5 that has the same processes as those in FIG. 4 will be omitted.

In the third section from the top in FIG. 5, the sequence controlling circuitry 120 excites the first slice by applying the IR pulse 46a and acquires data in the data acquisition 46b. This procedure corresponds to the procedure in FIG. 4 in which the sequence controlling circuitry 120 excites the first slice by applying the IR pulse 56a and acquires data in the data acquisition 56b. However, in FIG. 4, the sequence controlling circuitry 120 applies and performs the dummy pulse 59a, the data acquisition 55b, the IR pulse 56a, and the dummy acquisition 59e. In contrast, in FIG. 5, the sequence controlling circuitry 120 applies the IR pulse 46a and subsequently performs the data acquisition 45b. In other words, the sequence controlling circuitry 120 excites the third slice by applying the IR pulse 45a, and further performs the data acquisition 45b with such timing that overlaps with the IR pulse 46a used for exciting the first slice. With this arrangement, the number of times the dummy pulse is applied in the pulse sequence in FIG. 5 is smaller by 1 than in the pulse sequence in FIG. 4. It is therefore possible to shorten the image taking time period.

Further, in addition to the example above, the present embodiment is also able to further shorten the image taking time period by making a special arrangement for the nesting pattern among the slices. FIG. 6 illustrates an example of the arrangement.

FIG. 6 schematically illustrates another example of a pulse sequence applied by the sequence controlling circuitry 120. The reference characters 60a, 61a, 62a, 63a, 64a, 65a, 66a, 67a, and 68a denote IR pulses. The IR pulses 60a, 63a, and 66a excite the first slice. The IR pulses 61a, 64a, and 67a excite the second slice. The IR pulses 62a, 65a, and 68a excite the third slice. The reference characters 60b, 61b, 62b, 63b, 64b, 65b, 66b, 67b, and 68b denote data acquisitions. In the data acquisitions 60b, 63b, and 66b, data related to the first slice is acquired. In the data acquisitions 61b, 64b, and 67b, data related to the second slice is acquired. In the data acquisitions 62b, 65b, and 68b, data related to the third slice is acquired. The reference character 69d denotes a dummy pulse. The reference character 69b denotes a dummy acquisition.

In other words, with respect to the first slice, the sequence controlling circuitry 120 applies the IR pulses 60a, 63a, and 66a and acquires data in the data acquisitions 60b, 63b, and 66b. With respect to the second slice, the sequence controlling circuitry 120 applies the IR pulses 61a, 64a, and 67a and acquires data in the data acquisitions 61b, 64b, and 67b. With respect to the third slices, the sequence controlling circuitry 120 applies the IR pulses 62a, 63b, and 66b and acquires data in the data acquisitions 62b, 65b, and 68b. As observed from FIG. 6, in the series of pulse sequence, the sequence controlling circuitry 120 is able to acquire the data derived from three mutually-different TI periods with respect to each of the slices. In addition, in comparison to the example in FIG. 5, the number of times the dummy pulse is applied is smaller. It is therefore possible to further shorten the image taking time period.

Further, the pulse sequence applied by the sequence controlling circuitry 120 is not limited to the two-dimensional spin-echo EPI sequence. In other words, the pulse sequence does not necessarily have to be an EPI sequence. Further, the pulse sequence does not necessarily have to be one with spin echoes and may be a pulse sequence with gradient echoes, for example. Further, the flip angle of the IR pulses does not necessarily have to be 180 degrees. Also, the flip angles of the 90-degree pulses and the 180-degree pulses do not necessarily have to be 90 degrees and 180 degrees. Furthermore, the fat saturation pulses may be selective pulses or non-selective pulses and may be omitted.

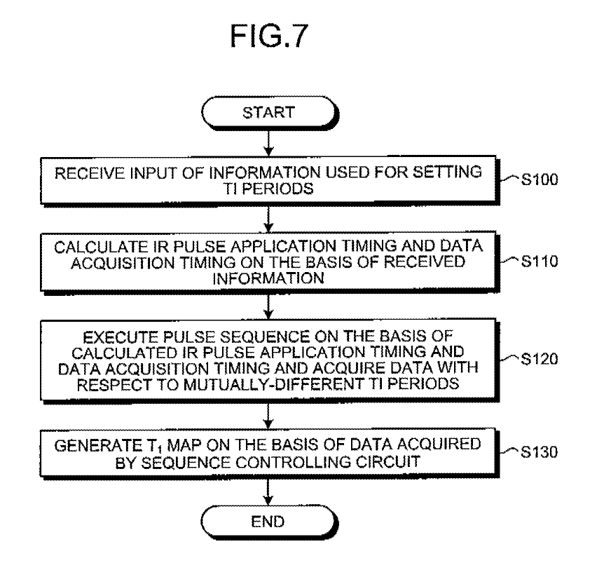

Next, with reference to FIG. 7, a flow in a process performed by the MRI apparatus 100 according to the first embodiment will be explained, from setting the parameter for the pulse sequence, followed by executing the pulse sequence, to generating the T₁ map. FIG. 7 is a flowchart for explaining an example of a procedure in the process performed by the MRI apparatus according to the first embodiment.

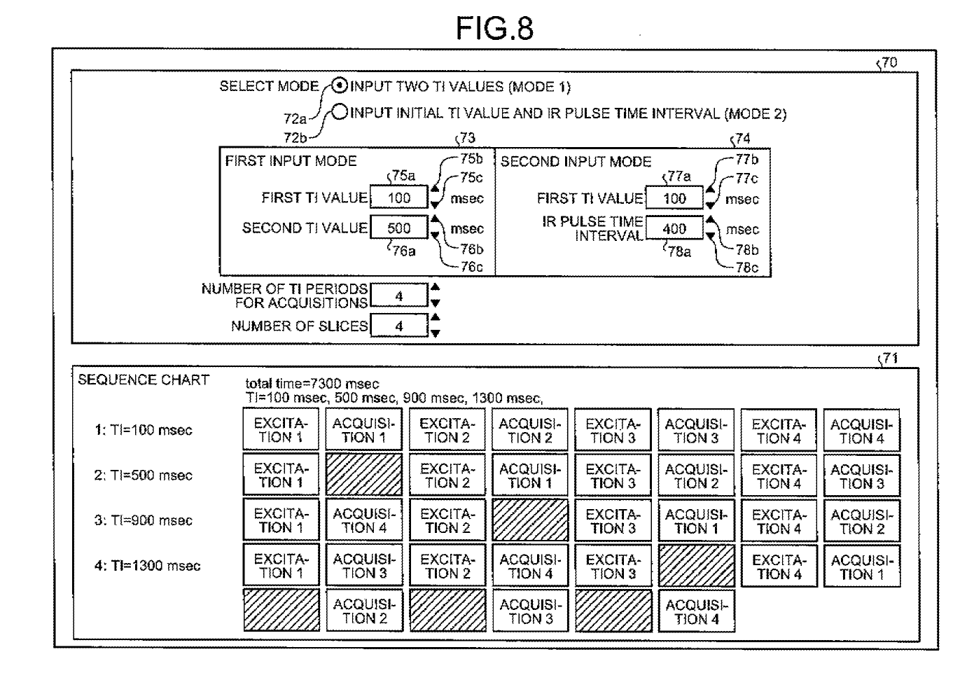

At first, by employing the receiving function 137, the processing circuitry 150 receives an input of information used for setting a TI period, via the input device 134, for example (step S100). An example of a GUI displayed on the display 135 during the process is illustrated in FIG. 8. FIG. 8 is a drawing illustrating the example of the GUI related to the MRI apparatus according to the first embodiment.

In FIG. 8, a display region 70 is a display region used for receiving, from the user, the input of the information used for setting the TI period. In contrast, a display region 71 is a display region used for displaying information about a pulse sequence to be executed, such as a sequence chart of the pulse sequence to be executed.

In the display region 70, buttons 72a and 72b are buttons to receive a selection of an input mode used for setting the TI period. The button 72a is a button to receive the selection of a first input mode in which inputs of a first TI value and a second TI value are received for the purpose of setting the TI period. The button 72b is a button to receive the selection of a second input mode in which inputs of a first TI value and an IR pulse application time interval are received for the purpose of setting the TI period.

A display region 73 is a display region used for receiving the inputs from the user in the first input mode. The input field 75a is an input field used for receiving the input of the first TI value from the user in the first input mode. The buttons 75b and 75c are buttons used for receiving changes in the first TI value. Further, the input field 75b is an input field used for receiving the input of the second TI value in the first input mode. The buttons 76b and 76c are buttons used for receiving changes in the second TI value.

A display region 74 is a display region used for receiving the inputs from the user in the second input mode. The input field 77a is an input field used for receiving the input of the first TI value from the user in the second input mode. The buttons 77b and 77c are input fields used for receiving changes in the first TI value. Further, the input field 78a is an input field used for receiving the input of a value of the IR pulse application time interval from the user in the second input mode. The buttons 78b and 78c are buttons used for receiving changes in the value of the IR pulse application time interval.

In addition to this configuration, for example, other inputs field may be provided to receive changes in values indicating the number of TI periods for the acquisitions and the number of slices.

Returning to the description of the flowchart in FIG. 7, when the user has selected the button 72a (the first input mode) at step S100, the processing circuitry 150 receives, by employing the receiving function 137, an input of information used for setting the TI period in the display region 73, for example. More specifically, by employing the receiving function 137, the processing circuitry 150 receives an input of the first TI value via the input field 75a and an input of the second TI value via the input field 76a. In this situation, the first TI value is the smallest of the TI values used for the data acquisitions, for example. The second TI value is the second smallest of the TI values used for the data acquisitions, for example. In contrast, when the user has selected the button 72b (the second input mode), by employing the receiving function 137, the processing circuitry 150 receives an input of information used for setting the TI period in the display region 74, for example. More specifically, by employing the receiving function 137, the processing circuitry 150 receives an input of the first TI value via the input field 77a and an input of a value indicating the time interval of a plurality of excitation pulses (e.g., a time interval between the IR pulses) via the input field 78a. In another example, a set of default values of TI periods may be determined in advance for each of various sites that can serve as a target of an image taking process, so that the processing circuitry 150 receives an input of a site serving as a target of the image taking process from the user. In that situation, the processing circuitry 150 performs the processes at step S110 and thereafter, on the basis of the set of TI periods corresponding to the input site.

Subsequently, the processing circuitry 150 calculates timing with which the excitation pulses (the IR pulses) are to be applied (application times) and timing with which data acquisitions are to be performed, on the basis of the information received from the user at step S100 (step S110). For example, when the first input mode was calculated, while the input first TI value was “100 msec” and the input second TI value was “500 msec” at step S100, the processing circuitry 150 determines that the time interval between the plurality of excitation pulses is 500 msec−100 msec=400 msec. Accordingly, the processing circuitry 150 determines the TI values to be “100 msec, 500 msec, 900 msec, 1,300 msec, and so on”. Subsequently, on the basis of a sequence chart of any of the pulse sequences explained with reference to FIGS. 3 to 6, the processing circuitry 150 calculates the application timing of the excitation pulses and the timing of the data acquisitions. The processing circuitry 150 causes the display region 71, for example, to display a pattern of the pulse sequence that was calculated in this manner and is to be executed at the following steps, as well as the application times, the TI values, and the like.

Further, for example, when the second input mode was calculated, while the input first TI value was “100 msec” and the input IR pulse time interval was “400 msec” at step S100, the processing circuitry 150 determines the TI values to be “100 msec, 500 msec, 900 msec, 1,300 msec, and so on”, which are calculated by sequentially adding integer multiples of the IR pulse time interval to the first TI value, and performs the same process.

After that, the sequence controlling circuitry 120 applies the plurality of excitation pulses (the inversion recovery pulses) at the application times calculated on the basis of the information received by the receiving function 137 at step S110. In other words, on the basis of the IR pulse application timing and the data acquisition timing calculated by the processing circuitry 150 at step S110, the sequence controlling circuitry 120 executes any of the pulse sequences explained with reference to FIGS. 3 to 6, for example, and acquires the data with respect to the mutually-different TI periods (step S120).

After that, by employing the generating function 136, the processing circuitry 150 generates a T₁ map on the basis of the data related to the mutually-different TI periods and acquired by the sequence controlling circuitry 120 at step S120 (step S130).

As explained above, in the first embodiment, the sequence controlling circuitry 120 is configured to acquire the data derived from the mutually-different TI periods and related to the plurality of slices, at such application times that the time intervals between the excitation pulses (the inversion recovery pulses) are constant. With this configuration, firstly, it is possible to suppress variation in the MTC effect among the TI periods that may be caused due to the variation in the number of times the excitation pulse is applied per unit time period. Secondly, because it is possible to manage the pulse sequences in the single sequence chart, it is possible to manage the entire pulse sequences with a single protocol (which is the unit in which the installation of the apparatus is performed). It is therefore possible to improve convenience for the user. For example, it is possible to omit a pre-scan which would be required for each of different protocols. It is therefore possible to shorten the image taking time period. Further, because it is possible to use the single protocol, the number of setting items is reduced. It is therefore expected that registration errors can be reduced, for example.

### Second Embodiment

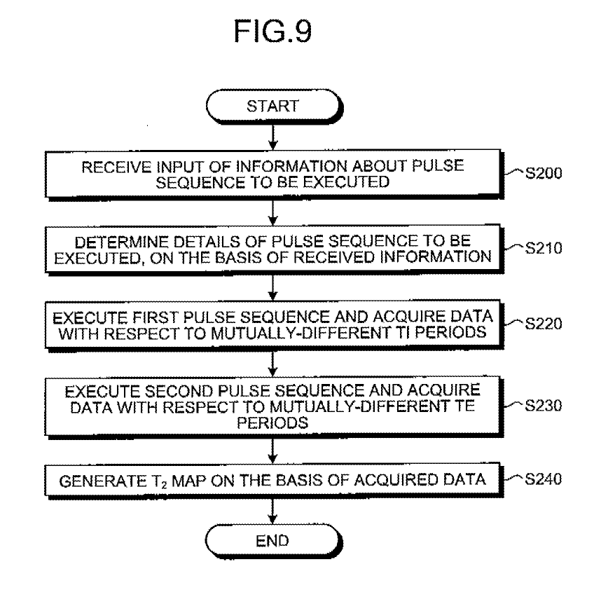

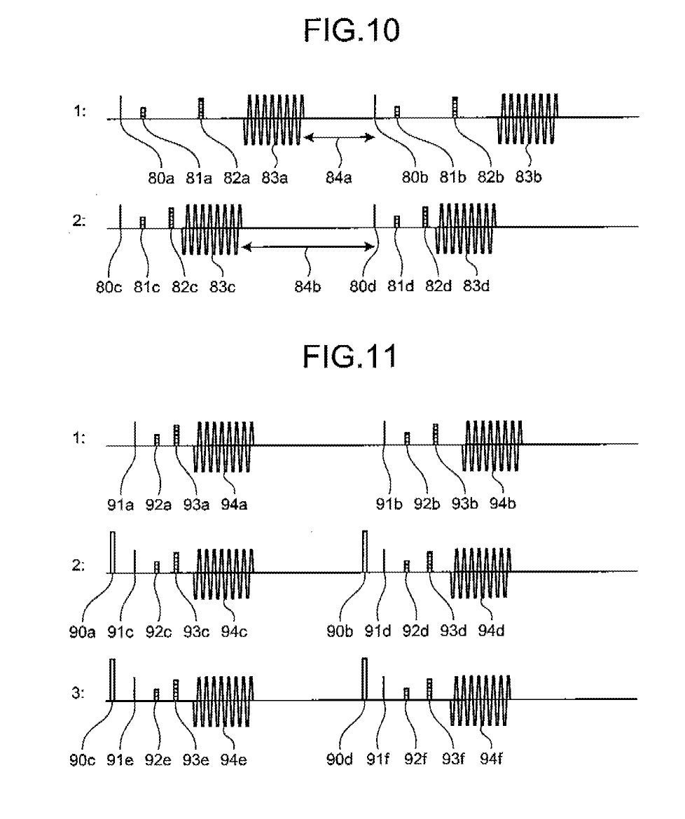

In the first embodiment, the example is explained in which the sequence controlling circuitry 120 is configured to apply the IR pulses at such application times that the time intervals between the IR pulses are constant and to acquire the data derived from the mutually-different TI periods with respect to the plurality of slices, and the processing circuitry 150 is configured to generate the T₁ map on the basis of the acquired data. In a second embodiment, an example will be explained with reference to FIGS. 9 and 10 in which the sequence controlling circuitry 120 is configured to apply a plurality of pulse sequences having mutually-different Echo Time (TE) periods, in addition to the pulse sequence described in the first embodiment, and the processing circuitry 150 is configured to generate a T₂ map on the basis of results.

FIG. 9 is a flowchart for explaining an example of a procedure in a process performed by an MRI apparatus according to the second embodiment. FIG. 10 is a drawing for explaining a pulse sequence executed by the MRI apparatus according to the second embodiment.

First, with reference to FIG. 10, a pulse sequence that is used in the second embodiment in addition to the pulse sequence explained in the first embodiment will be explained. FIG. 10 illustrates an example of the additional pulse sequence. In the following sections, the pulse sequence explained in the first embodiment will be referred to as a first pulse sequence, whereas the pulse sequence illustrated in FIG. 10 will be referred to as a second pulse sequence.

In FIG. 10, the reference characters 80a, 80b, 80c, and 80d are fat saturation pulses used for suppressing signals of fat. The reference characters 81e, 81b, 81c, and 81d denote 90-degree pulses. The reference characters 82a, 82b, 82c, and 82d denote 180-degree pulses. By combining each of the 90-degree pulses with a corresponding one of the 180-degree pulses, an echo is generated. While the echo is being generated, an acquisition is performed. The reference characters 83a, 83b, 83c, and 83d denote data acquisitions. The standby time periods 84a and 84b each denote a time period from when the data acquisition is finished to when the acquisition in the next cycle is started.

First, in the top section of FIG. 10, after applying the fat saturation pulse 80a, with respect to the first slice, the sequence controlling circuitry 120 applies the 90-degree pulse 81a and the 180-degree pulse 82a, so as to generate a spin echo. While the spin echo is being generated, the sequence controlling circuitry 120 performs the data acquisition 83a on slice 1. After the data acquisition is completed, the sequence controlling circuitry 120 stands by for the duration of the standby period 84a. Subsequently, after applying the fat saturation pulse 80b, with respect to the second slice, the sequence controlling circuitry 120 applies the 90-degree pulse 81b and the 180-degree pulse 82b so as to generate a spin echo. While the spin echo is being generated, the sequence controlling circuitry 120 performs the data acquisition 83b on slice 1.

After that, in the bottom section of FIG. 10, after applying the fat saturation pulse 80c, with respect to the first slice, the sequence controlling circuitry 120 similarly applies the 90-degree pulse 81c and the 180-degree pulse 82c, so as to generate: a spin echo. While the spin echo is being generated, the sequence controlling circuitry 120 performs the data acquisition 83c on slice 1. The sequence controlling circuitry 120 performs the data acquisition by using a TE period varied from the TE period in the top section of FIG. 10. In this situation, the TE period denotes the time period from the 90-degree pulse 81a to the data acquisition 83a in the top section of FIG. 10 and denotes the time period from the 90-degree pulse 81c to the data acquisition 83c in the bottom section of FIG. 10. After the data acquisition is completed, the sequence controlling circuitry 120 stands by for the duration of the standby time period 84b. In this situation, the standby time period 84b is arranged to have a different length from that of the standby time period 84a. More specifically, the standby time period 84b during which the sequence controlling circuitry 120 stands by is arranged in such a manner that the time interval from the fat saturation pulse 80a to the fat saturation pulse 80b (or the time interval between the 90-degree pulse 81a and the 90-degree pulse 81b) is equal to the time interval from the fat saturation pulse 80c to the fat saturation pulse 80d. Subsequently, after applying the fat saturation pulse 80d, with respect to the second slice, the sequence controlling circuitry 120 applies the 90-degree pulse 81d and the 180-degree pulse 82d, so as to perform the data acquisition 83d while using the same TE period as that used for the first slice.

As explained above, in the second embodiment, the sequence controlling circuitry 120 further performs the plurality of acquisitions while varying the TE periods. Because the data derived from the varied TE periods is obtained, the processing circuitry 150 is able to generate the T₂ map.

Returning to the description of FIG. 9, at first, the processing circuitry 150 receives an input of information about the pulse sequence to be executed (step S200). The information about the pulse sequence to be executed may be, for example, information used for setting the TI periods explained in the first embodiment and information about the varied TE periods. By employing the receiving function 137, the processing circuitry 150 receives, from the input device 134, the input of the information about the TE periods, for example, in addition to the information used for setting the TI periods explained in the first embodiment. The information about the TE periods may be, for example, information indicating that the TE periods are 200 msec, 400 msec, and 600 msec.

After that, on the basis of the received information, the processing circuitry 150 determines details of the pulse sequence to be executed (step S210). In addition to the process corresponding to step S110 in FIG. 7 in the first pulse sequence, the processing circuitry 150 sets, for example, the standby time period in the second pulse sequence, which is a pulse sequence in which the TE periods are varied. Subsequently, for example, by executing the first pulse sequence explained in the first embodiment, the processing circuitry 150 acquires the data with respect to the mutually-different TI periods (step S220). After that, by executing the pulse sequence in which the TE periods are varied, the sequence controlling circuitry 120 acquires the data with respect to the mutually-different TE periods (step S230). By employing the generating function 136, the processing circuitry 150 generates a T₂ map on the basis of the data derived from the mutually-different TI periods acquired by the sequence controlling circuitry 120 at step S220 and the data derived from the mutually-different TE periods acquired at step S230 (step S240). Further, as explained in the first embodiment, by employing the generating function 136, the processing circuitry 150 generates a T₁ map on the basis of the data derived from the mutually-different TI periods acquired by the sequence controlling circuitry 120 at step S220.

The processes at step S220 and step S230 do not necessarily have to be performed in the order described above. The sequence controlling circuitry 120 may perform the process at step S220 after performing the process at step S230.

The MRI apparatus 100 according to the second embodiment is able to generate the T₂ map while maintaining the advantageous characteristics explained in the first embodiment.

### Third Embodiment

In the first embodiment, the example is explained in which the sequence controlling circuitry 120 acquires the data with respect to the mutually-different TI periods by applying the inversion recovery pulses. In a third embodiment, in addition to the data acquisitions explained in the first embodiment, the sequence controlling circuitry 120 acquires data by additionally executing sequences in which no inversion recovery pulse is applied. Each of the sequences in which no inversion recovery pulse is applied is considered to be equivalent to a sequence in which an inversion recovery pulse is applied and which has an infinite TI period. By also executing the sequences in which no inversion recovery pulse is applied, the sequence controlling circuitry 120 is able to further improve the image quality.

FIG. 11 is a drawing for explaining a pulse sequence executed by an MRI apparatus according to the third embodiment.

In FIG. 11, the reference characters 91a, 91b, 91c, 91d, 91e, and 91f denote IR pulses that are excitation pulses to invert the longitudinal magnetization of the tissue. The reference characters 90a, 90b, 90c, and 90d denote fat saturation pulses used for suppressing signals of fat. The reference characters 91a, 91b, 91c, 91d, 91e, and 91f denote 90-degree pulses. The reference characters 93a, 93b, 93c, 93d, 93e, and 93f denote 180-degree pulses. By combining each of the 90-degrees with a corresponding one of the 180-degree pulses, an echo is generated. While the echo is being generated, an acquisition is performed. The reference characters 94a, 94b, 94c, 94d, 94e, and 94f denote data acquisitions.

The middle section of FIG. 11 corresponds to the top section of FIG. 3, whereas the bottom section of FIG. 11 corresponds to the bottom section of FIG. 3. Thus, duplicate explanations will be omitted. The pulse sequence in FIG. 11 is considered to be a sequence obtained by adding a sequence including no inversion recovery pulse to the beginning of the sequence illustrated in FIG. 3, for example. In other words, at first, after applying the fat saturation pulse 91a, the sequence controlling circuitry 120 applies, with respect to the first slice, the 90-degree pulse 92a and the 180-degree pulse 93a, so as to generate a spin echo. While the spin echo is being generated, the sequence controlling circuitry 120 performs the data acquisition 94a on slice 1. Subsequently, after applying the fat saturation pulse 91b, the sequence controlling circuitry 120 applies, with respect to the second slice, the 90-degree pulse 92b and the 180-degree pulse 93b, so as to generate a spin echo. While the spin echo is being generated, the sequence controlling circuitry 120 performs the data acquisition, 94b on the second slice. After repeatedly performing the acquisitions on all the slices in this manner, the sequence controlling circuitry 120 executes the pulse sequence illustrated in FIG. 3. In other words, the sequence controlling circuitry 120 performs the acquisitions on the plurality of slices, the acquisitions including the acquisitions that involve the application of the inversion recovery pulse and the acquisitions that do not involve the application of the inversion recovery pulse.

As explained above, by also executing the sequences in which no inversion recovery pulse is applied, the sequence controlling circuitry 120 is able to further improve the image quality.

### Fourth Embodiment

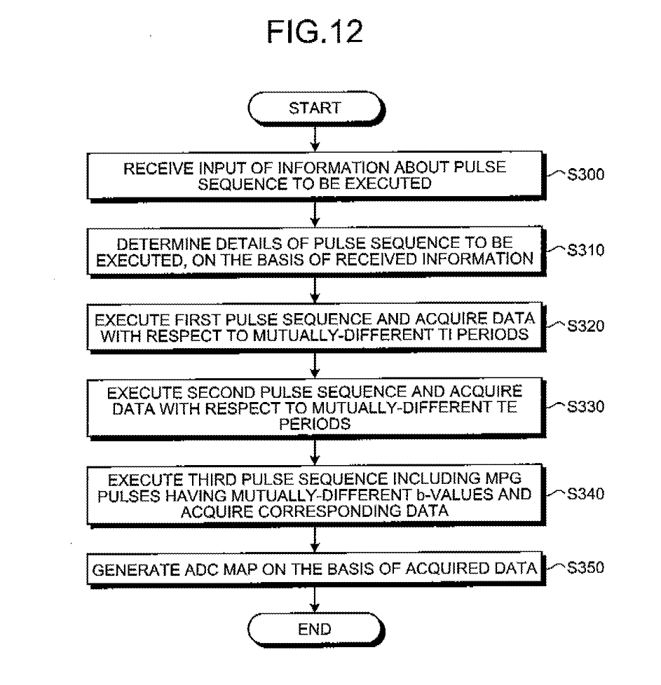

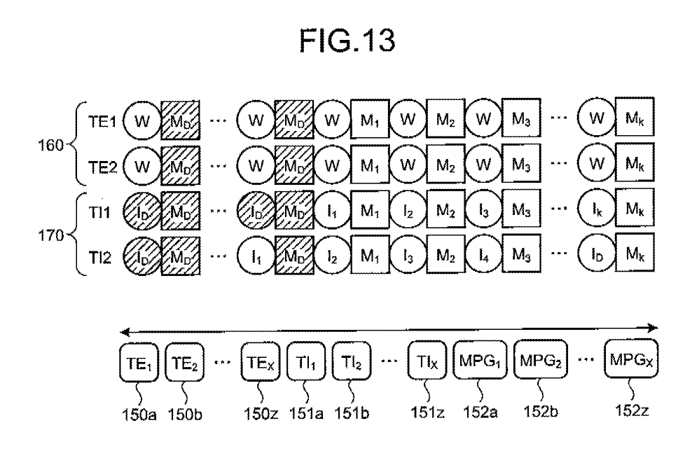

In a fourth embodiment, with reference to FIGS. 12 and 13, an example will be explained in which it is possible to generate an Apparent Diffusion Coefficient (ADC) map while using the same protocol, as a result of the sequence controlling circuitry 120 executing, in addition to the configuration in the second embodiment, a pulse sequence including Motion Probe Gradient (MPG) pulses while varying a b-value. FIG. 12 is a flowchart for explaining an example of a procedure in a process performed by an MRI apparatus according to the fourth embodiment. FIG. 13 is a drawing for explaining a process performed by the MRI apparatus according to the fourth embodiment.

First, a pulse sequence executed by the sequence controlling circuitry 120 will be explained, with reference to FIG. 13.

Each of the sequences 151a, 151b, . . . , and 151z is a set of pulse sequences used for acquiring data while varying the TI periods as explained in the first embodiment. A detailed configuration of each of the pulse sequences is illustrated in the section indicated with a bracket 170. For example, the sequence indicated with “TI₁” in the bracket 170 corresponds to the sequence 151a. The sequence indicated with “TI₂” in the bracket 170 corresponds to the sequence 151b. These pulse sequences will be referred to as first pulse sequences.

Each of the sequences 150a, 150b, . . . , and 150z is a set of pulse sequences used for acquiring data while varying the TE periods as explained in the second embodiment. A detailed configuration of each of the pulse sequences is illustrated in the section indicated with a bracket 160. or example, the sequence indicated with “TE₁,” in the bracket 160 corresponds to the sequence 150a. The sequence indicated with “TE₂” in the bracket 160 corresponds to the sequence 150b. The symbol “W” schematically denotes such a part of the pulse sequence that is other than a data acquisition. These pulse sequences will be referred to as second pulse sequences.

Each of the sequences 152a, 152b, . . . , and 150z is a set of pulse sequences used for acquiring data by applying MPG pulses while varying the b-value. For example, the sequences 152a, 152b, . . . , and 152z are pulse sequences that are the same as one another except for the b-value of the MPG pulses. In other words; the sequences 152a, 152b, . . . , and 152z are different from one another only for the b-values of the MPG pulses. In this situation, for the b-values, it is necessary to vary only the intensity among the applied pulses, and there is no need to vary the sequence chart. Accordingly, the sequence controlling circuitry 120 is able to manage the pulse sequences having the mutually-different b-values, by using mutually the same protocol. These pulse sequences will be referred to as third pulse sequences.

At steps S320 through S340 in FIG. 12 explained later, the sequence controlling circuitry 120 sequentially executes, for example, the pulse sequences 150a, 150b, . . . , 150z, 151a, 151b, . . . 151z, 152a, 152b, . . . , and 152z.

Returning to the description of FIG. 12, at first, the processing circuitry 150 receives an input of information about the pulse sequence to be executed (step S300). The information about the pulse sequence to be executed may be, for example, information about the b-values of the MFG pulses, in addition to the information used for setting the TI periods explained in the first embodiment and the information about the varied TE periods explained in the second embodiment.

After that, on the basis of the received information, the processing circuitry 150 determines details of the pulse sequence to be executed (step S310). In addition to the process corresponding to step S110 in FIG. 7 in the first pulse sequences, the processing circuitry 150 sets the standby time periods, for example, in the second pulse sequences, which are the pulse sequences in which the TE periods are varied. Further, on the basis of the information about the b-values input at step S300, the processing circuitry 150 determines details of the third pulse sequences. Subsequently, the processing circuitry 150 acquires data with respect to the mutually-different TI periods, by executing the first pulse sequence explained in the first embodiment, for example (step S320). After that, the sequence controlling circuitry 120 acquires data with respect to the mutually-different TE periods, by executing the pulse sequence in which the TE periods are varied explained in the second embodiment (step S330). Subsequently, the sequence controlling circuitry 120 further executes the third pulse sequences represented by the plurality of acquisitions in which the b-values of the MPG pulses are varied, so as to acquire corresponding data (step S340). By employing the generating function 136, the processing circuitry 150 generates an ADC map on the basis of the data acquired by the sequence controlling circuitry 120 at steps S320 through S340 (step S350). Further, by employing the generating function 116, the processing circuitry 150 also generates a T₁ map and a T₂ map together.

The processes at steps S320, S330, and S340 do not necessarily have to be performed in the order described above.

As explained above, the MRI apparatus 100 according to the fourth embodiment is able to generate the ADC map by using the single protocol, while maintaining the advantageous characteristics explained in the first embodiment.

By using the MRI apparatus according to at least one aspect of the embodiments described above, it is possible to improve the image quality or to enhance usability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
sequence controlling circuitry configured, when executing a pulse sequence on a plurality of slices by which an inversion recovery pulse to invert longitudinal magnetization of a tissue between a positive value and a negative value is applied to a predetermined one of the plurality of slices, and when a standby time period has elapsed a data acquisition is subsequently performed on the predetermined one of the plurality of slices, to exercise control so that an inversion recovery pulse is applied to another one of the plurality of slices during the standby time period and so that a data acquisition is performed multiple times on each of the plurality of slices while varying the standby time period; and
processing circuitry configured to generate an image by using data acquired by the data acquisitions, wherein
the sequence controlling circuitry exercises control so that time intervals between the inversion recovery pulses are constant.

2. The magnetic resonance imaging apparatus according to claim 1, wherein the sequence controlling circuitry is configured to apply a dummy pulse when the data acquisition is not performed on any of the plurality of slices and during a time period between an application time at which an inversion recovery pulse is applied to a first slice and another application time at which an inversion recovery pulse is applied to a second slice different from the first slice.

3. The magnetic resonance imaging apparatus according to claim 1, wherein the processing circuitry generates a T₁ map by using the data acquired by the data acquisitions.

4. The magnetic resonance imaging apparatus according to claim 1, wherein, by performing the data acquisition multiple times, the sequence controlling circuitry acquires a plurality of pieces of data TI (inversion time) periods of which are different from one another.

5. The magnetic resonance imaging apparatus according to claim 1, wherein
the processing circuitry receives an input of a first TI value and an input of a second TI value, and
the sequence controlling circuitry applies the inversion recovery pulse at application times calculated on a basis of information received by the processing circuitry.

6. The magnetic resonance imaging apparatus according to claim 1, wherein
the processing circuitry receives an input of a first TI value and an input of the time interval between the inversion recovery pulses, and
the sequence controlling circuitry applies the inversion recovery pulses with timing calculated on a basis of information received by the processing circuitry.

7. The magnetic resonance imaging apparatus according to claim 1, wherein the sequence controlling circuitry further performs a plurality of acquisitions while varying a TE (Echo Time) period.

8. The magnetic resonance imaging apparatus according to claim 1, wherein the sequence controlling circuitry further performs a plurality of acquisitions while varying a b-value.

9. The magnetic resonance imaging apparatus according to claim 1, wherein the sequence controlling circuitry performs the acquisitions on the plurality of slices, the acquisitions including at least one acquisition that involves an application of the inversion recovery pulse and at least one acquisition that does not involve an application of the inversion recovery pulse.

10. The magnetic resonance imaging apparatus according to claim 7, wherein the processing circuitry generates a T₂ map on a basis of the data acquired by the sequence controlling circuitry.

11. The magnetic resonance imaging apparatus according to claim 8, wherein the processing circuitry generates an Apparent Diffusion Coefficient (ADC) map on a basis of the data acquired by the sequence controlling circuitry.

12. A magnetic resonance imaging method implemented by a magnetic resonance imaging apparatus, the magnetic resonance imaging method comprising:
when executing a pulse sequence on a plurality of slices by which an inversion recovery pulse to invert longitudinal magnetization of a tissue between a positive value and a negative value is applied to a predetermined one of the plurality of slices, and when a standby time period has elapsed a data acquisition is subsequently performed on the predetermined one of the plurality of slices, by sequence controlling circuitry, exercising control so that an inversion recovery pulse is applied to another one of the plurality of slices during the standby time period and so that a data acquisition is performed multiple times on each of the plurality of slices while varying the standby time period; and
generating, by processing circuitry, an image while using data acquired by the data acquisitions, wherein the sequence controlling circuitry exercises control so that time intervals between the inversion recovery pulses are constant.
